(19) United States
(12) Patent Application Publication
(10) Pub. No.: US 2026/0190241 A1
(43) Pub. Date: Jul. 2, 2026

(54) METHOD FOR FORMING BLIND VIAS AND METHOD FOR MANUFACTURING PACKAGING SUBSTRATE

(71) Applicant: Absolics Inc., Covington, GA (US)

(72) Inventors: Chun Jae LEE, Covington, GA (US); DAE HWAN KIM, Covington, GA (US)

(73) Assignee: Absolics Inc., Covington, GA (US)

(21) Appl. No.: 19/414,276

(22) Filed: Dec. 10, 2025

Related U.S. Application Data
(60) Provisional application No. 63/740,348, filed on Dec. 31, 2024.

(51) Int. Cl. H05K 3/00; H05K 3/42

(52) U.S. Cl. CPC H05K 3/0035; H05K 3/0055; H05K 3/421

(57) ABSTRACT

According to the embodiments, a method for forming blind vias and a method for manufacturing a packaging substrate comprise: a protective-layer arranging operation of preparing a substrate in which a machining protective layer is disposed over an insulating layer; a laser operation of forming a blind via at a predetermined position on the machining protective layer; and a cleaning operation of removing particulate by-products or smear generated in the blind via and removing the machining protective layer, thereby forming a blind via in the insulator.

### CROSS-REFERENCE TO RELATED APPLICATION

This application claims priority of U.S. Provisional Patent Application No. 63/740,348, filed on December 31, 2024, the entire disclosure of which is hereby incorporated by reference for all purposes.

### BACKGROUND

### Technical Field

The embodiments relate to a method for forming blind vias and a method for manufacturing a packaging substrate that may facilitate removal of processing by-products and obtain a damage-free surface.

### Description of Related Art

Laser drilling refers to forming small holes and special via holes in electronic devices of multilayer substrates by using laser light to interconnect layers.

Such a laser drilling technique is one of the via-hole machining methods that emerged to resolve limitations in circuit miniaturization and increases in machining cost that arise when using mechanical drills to process via holes corresponding to interlayer connection paths of a multilayer substrate.

By the laser drilling technique, via holes of a multilayer substrate may be formed more finely than by conventional mechanical machining, and machining costs may also be greatly reduced; however, other issues have arisen.

In the laser drilling technique currently used for manufacturing multilayer substrates, when forming a single hole, a hole-cleaning operation at the end is required to remove fine foreign substances generated inside the hole upon forming the via hole.

If perfect cleaning is not achieved, plating defects may occur during copper electroplating after desmear and cleaning processes. In addition, after forming a hole of desired size, it is necessary to perform a laser shot again for cleaning, which may cause a hole having a bore larger than the design dimension to be formed. To prevent this, the hole size must be designed and machined in advance in consideration of the final shot, which may cause problems and inconveniences such as an increase in per-unit man-hours, including the inconvenience of having to design and machine with the final shot in mind.

Related art includes Korean Registered Patent No. 10-0859206 and Korean Laid-Open Patent Publication No. 10-2020-0069645.

### SUMMARY

In some embodiments, provide a method for forming blind vias and a method for manufacturing a packaging substrate, which may facilitate removal of processing by-products and obtain a damage-free surface.

According to the embodiments, the method for forming blind vias includes: a protective-layer arranging operation of preparing a substrate in which a machining protective layer is disposed on an insulating layer; a laser operation of forming a blind via at a predetermined location on the machining protective layer; and a cleaning operation of removing particulate by-products or smear generated in the blind via and removing the machining protective layer, thereby forming a blind via in the insulator.

The machining protective layer may be a metal layer.

The metal layer may include titanium, a titanium–copper composite layer, or copper.

The machining protective layer may be an organic layer or an organic–inorganic composite layer.

The machining protective layer may include a polyimide resin, a polyethylene terephthalate resin, a polyurethane resin, or a polyacrylic resin.

When the laser is irradiated in the laser operation, a part of the machining protective layer and a part of the insulating layer may be etched, and the by-products may scatter to form particulate by-products or smear.

The cleaning operation may include: a desmear process of removing the particulate by-products or smear by applying plasma or a desmear solution; and a protective-layer removal process of removing the machining protective layer from the substrate that has undergone the removal process.

The machining protective layer may have a thickness of 10 µm or more and 500 µm or less.

A difference between the surface roughness Ra of the insulating layer before formation of the machining protective layer and the surface roughness Ra of the insulating layer after the cleaning operation may be 600 nm or less.

The laser irradiation may be ultraviolet having a pulse width of 400 nm or less, a pulse energy of 1 µJ or more, and a pulse repetition rate of 10 Hz or more.

According to another embodiment, a method for manufacturing a packaging substrate includes: Operation A of preparing a glass core having through vias and a core electrically conductive layer that is an electrically conductive layer disposed on the glass core; Operation B of preparing a core insulating layer by disposing an insulating layer on a surface of the glass core; Operation C of forming blind vias in the core insulating layer according to the method for forming blind vias of claim 1; Operation D of forming electrodes in the blind vias and forming an electrically conductive layer on the core insulating layer by providing an electrically conductive layer pattern; and Operation E of preparing an upper insulating layer by disposing an insulating layer on the electrically conductive layer.

In Operation B, the core insulating layer may be prepared by disposing and curing the insulating layer.

### BRIEF DESCRIPTION OF THE DRAWINGS

FIG. 1 is a conceptual cross-sectional view illustrating a method of manufacturing a packaging substrate according to an embodiment.

FIGS. 2 and 3 are conceptual cross-sectional views respectively illustrating a process of forming an upper layer in the method of manufacturing a packaging substrate according to an embodiment.

FIG. 4 is a conceptual view showing a via electrode manufactured according to an embodiment, as seen from above (upper) and in cross-section (lower).

### DESCRIPTION OF THE EMBODIMENTS

Hereinafter, exemplary embodiments will be described in detail with reference to the accompanying drawings so that a person having ordinary skill in the art may readily practice the invention. However, the invention may be embodied in various different forms and is not limited to the embodiments set forth herein. Throughout the specification, like reference numerals denote like elements.

Throughout the specification, the term “combination thereof” included in a Markush-type expression is intended to mean one or more mixtures or combinations selected from the group of components recited in the Markush-type expression, and to mean that one or more selected from the group of those components may be included.

In this specification, terms such as “first,” “second,” or “A,” “B” are used to distinguish between like terms. In addition, unless the context clearly indicates otherwise, singular forms include plural forms.

In this specification, “~-based” may mean that the compound contains the moiety corresponding to “~” or a derivative of “~” within the compound.

In this specification, that B is disposed over A means that B is positioned directly on A in contact therewith, or that B is positioned over A with another layer interposed therebetween; it is not to be construed as being limited to B being in contact with the surface of A.

In this specification, that B is connected to A means that A and B are connected directly, or are connected via another component interposed between A and B, and unless otherwise specified, it is not to be construed as being limited to A and B being directly connected.

In this specification, singular terms, unless otherwise specifically described, shall be interpreted to include singular or plural as understood from the context.

In the drawings of this specification, the shapes, relative sizes, angles, and the like of the respective components are illustrative and may be exaggerated for purposes of description, and the scope of rights is not to be construed as limited to the drawings.

In this specification, that A and B are adjacent means that A and B are positioned in contact with each other, or are positioned close to each other without being in contact. Unless otherwise specified, the expression that A and B are adjacent is not to be construed as limited to A and B being positioned in contact.

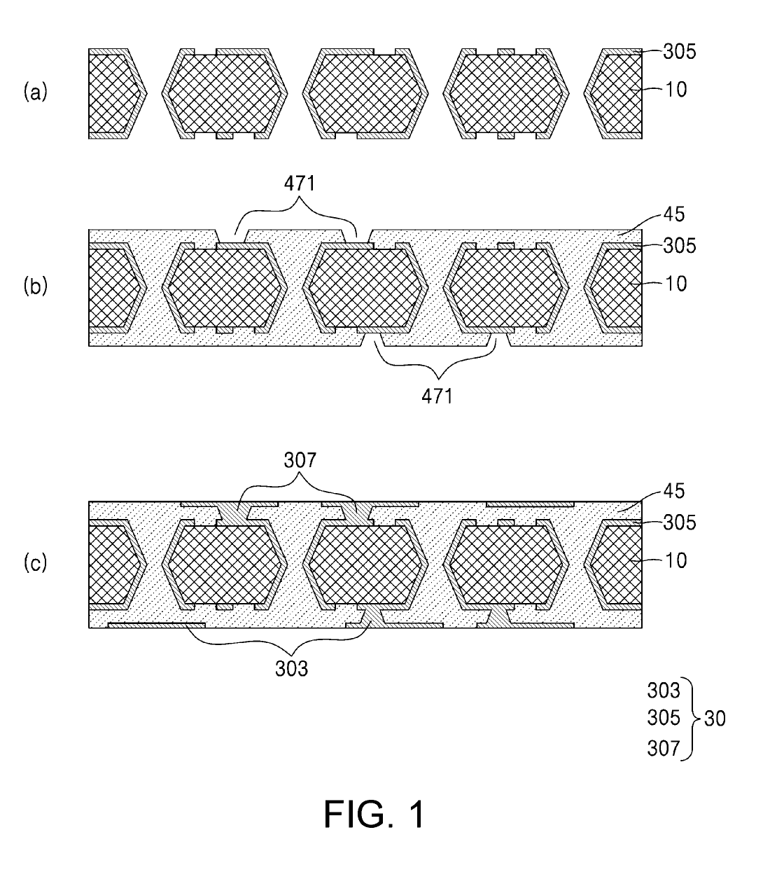

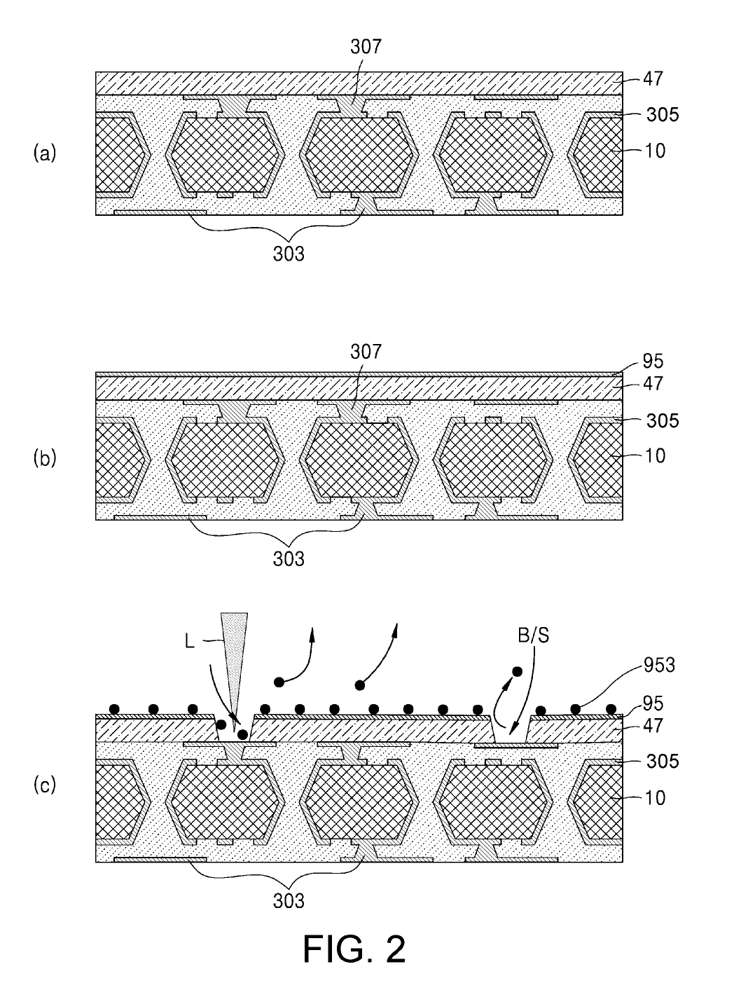

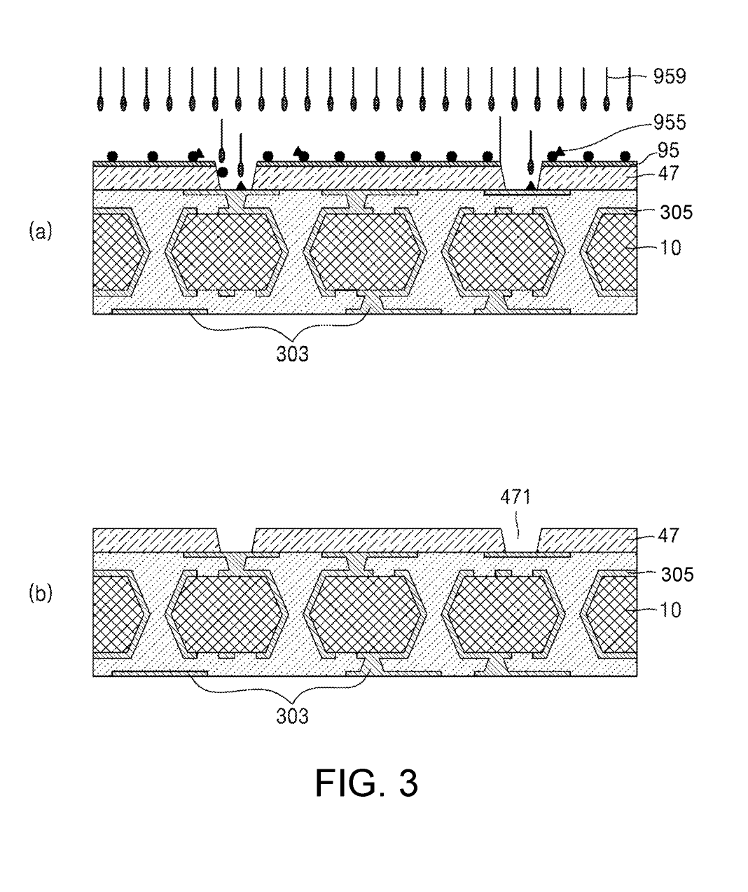

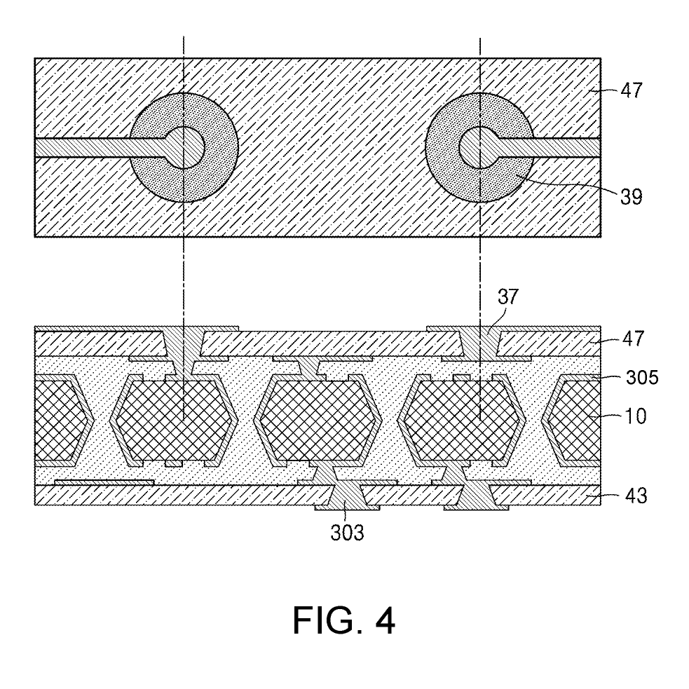

FIG. 1 is a conceptual cross-section illustrating a method of manufacturing a packaging substrate according to an embodiment; FIGS. 2 and 3 are conceptual cross-sections respectively illustrating a process of forming an upper layer in the method of manufacturing a packaging substrate according to an embodiment; and FIG. 4 is a conceptual view showing a via electrode manufactured according to an embodiment as viewed from above (upper) and in cross-section (lower). The embodiments will be described in greater detail with reference to the drawings.

To achieve the above object, a method of forming blind vias according to one embodiment comprises a protective-layer arranging operation; a laser operation; and a cleaning operation.

The protective-layer arranging operation is an operation of preparing a substrate in which a machining protective layer 95 is disposed over an insulating layer.

A blind via 471 is formed at a predetermined location after the insulating layer is formed. For example, the blind via 471 may be formed by laser etching or plasma etching. Hereinafter, a case of laser etching will be described by way of example; a case of plasma etching may likewise be applied in a manner similar to the description below.

The machining protective layer 95 is disposed over the surface of the insulating layer to protect the insulating layer from a laser or plasma ions. In addition, during cleaning after blind-via formation, the machining protective layer 95 may be removed.

The machining protective layer 95 may be an inorganic layer. For example, the inorganic machining protective layer 95 may be a metal layer or an insulating layer, but is not limited thereto.

The machining protective layer 95 may be a metal layer. For example, the metallic machining protective layer 95 may comprise titanium, a titanium–copper composite layer, or copper. For example, the metallic machining protective layer 95 may be formed by a deposition or sputtering process, but is not limited thereto. For example, by a method such as physical vapor deposition (PVD), a metal layer of about 10 nm or more, about 15 nm or more, about 20 nm or more, about 25 nm or more, or about 30 nm or more may be formed. In addition, a metal layer of about 400 nm or less, about 350 nm or less, about 300 nm or less, or about 250 nm or less may be formed.

The machining protective layer 95 may be an organic layer. For example, the organic layer may comprise a polyimide resin, a polyethylene terephthalate resin, a polyurethane resin, or a polyacrylic resin. For example, an organic layer formed in a film form may be applied as the machining protective layer 95 by laminating it over a target to be protected. The organic machining protective layer 95 may have a thickness of about 10 µm or more, about 20 µm or more, about 30 µm or more, about 40 µm or more, or about 50 µm or more. The thickness may be about 500 µm or less, about 450 µm or less, about 400 µm or less, about 350 µm or less, about 300 µm or less, about 250 µm or less, about 200 µm or less, or about 150 µm or less.

The machining protective layer 95 may be an organic–inorganic composite layer. For example, the organic–inorganic composite may be a mixture in which an inorganic material is mixed into a polymer resin. For example, the organic–inorganic composite machining protective layer 95 may be in a film form.

The machining protective layer 95 may have a thickness of about 10 µm or more and about 500 µm or less.

The thickness of the machining protective layer may vary depending on the material applied as the machining protective layer. If the machining protective layer is excessively thick, there is a concern that excessive energy will be consumed or the process will become complicated in the removal process. Conversely, if the machining protective layer is too thin, it may be difficult to obtain sufficient protective effects, or removal may rather become tricky.

When the thickness of the machining protective layer 95 is within the above range, the insulating layer is sufficiently protected during the via-formation and cleaning processes, while the layer can subsequently be removed in a stable manner.

When the machining protective layer 95 is a metal layer or an organic film layer, it has the advantage that application in manufacturing is relatively easy and it is relatively easy to carry out additional processes.

The laser operation is an operation of forming the blind via 471 at a predetermined location on the machining protective layer 95.

For example, the blind-via formation may be performed by irradiating a laser L.

The laser L may remove the insulating layer and may selectively remove the machining protective layer 95, which is a layer comprising a metal layer or a polymer.

If necessary, the laser L applied to remove the insulating layer and the laser L applied to partially remove the machining protective layer 95 may be applied separately, or the same laser may be applied for both. That they may be applied separately may mean that the type of laser is changed. Alternatively, it may mean that parameters such as the intensity of the laser light or the pulse width are adjusted.

In the laser operation, when the laser L is irradiated, a portion of the machining protective layer 95 and a portion of the insulating layer may be etched, and the by-products may scatter to form particulate by-products 953 or smear 955.

By way of example, irradiation of the laser L may apply a UV laser having a pulse width of 400 nm or less. The pulse width may be 380 nm or less, 360 nm or less, 340 nm or less, 320 nm or less, or 300 nm or less. The pulse width may be 100 nm or more. When a laser having such a pulse width is applied, a polymer resin material and a metal material may be removed together along with removal of the insulating layer.

The laser L may have a pulse energy of 1 µJ or more, 10 µJ or more, 100 µJ or more, 1 mJ or more, 10 mJ or more, 50 mJ or more, 75 mJ or more, or 100 mJ or more. The pulse energy may be 1 J or less, 900 mJ or less, 800 mJ or less, or 750 mJ or less. By applying such pulse energy, the insulating layer and the like may be removed more efficiently.

The laser L may have a pulse repetition rate of 10 Hz or more, 50 Hz or more, 100 Hz or more, 300 Hz or more, 600 Hz or more, 1 kHz or more, 10 kHz or more, 30 kHz or more, 50 kHz or more, or 100 kHz or more. The pulse repetition rate may be 500 kHz or less, 300 kHz or less, 200 kHz or less, or 150 kHz or less.

When the laser L is applied within the above ranges, polymer materials and metal materials may be removed efficiently together with the insulating layer. Although the above description focuses on a UV laser, other lasers having different characteristics (e.g., long-wavelength lasers such as a CO₂ laser or a CO laser) may also be applied as needed in consideration of the properties of the materials. For example, irradiation of the laser L may also apply an IR wavelength of 1 µm or less, or 0.9 µm or less.

By way of example, when a PET film is applied as the machining protective layer, the pulse width of the UV laser may be at or below the picosecond range. Alternatively, a Deep-UV wavelength having a pulse width of 300 nm or less may be used. The insulating layer may be removed with a nanosecond-UV pulse laser.

By way of example, when the machining protective layer is a photoresist layer or a polyimide layer, a nanosecond-UV pulse laser may be applied.

By way of example, when the machining protective layer is a PVD metal film, machining may be performed with a nanosecond-UV pulse laser.

However, in the blind-via formation process by the laser, the removed insulating layer and the like may become processing by-products and form particulate by-products or smear.

If such particulate by-products remain in the blind via, cleaning may become difficult in subsequent processes, and open circuits or the like may occur in subsequent processes. Accordingly, to facilitate via formation and to proceed efficiently with later processes, blowing and/or suction (B/S) may be performed simultaneously with the laser irradiation or after the laser irradiation. As the blowing gas, for example, CDA (clean dry air) or N₂ may be applied, but the invention is not limited thereto.

The particulate by-products or smear may remain partly within the blind via and may also fall and remain on the insulating layer. In conventional examples, because such particulate by-products or smear fell onto the insulating layer, removal thereof during subsequent cleaning was not easy.

In the embodiments, a machining protective layer 95 is disposed over the insulating layer.

Therefore, particulate by-products or smear do not fall directly onto the surface of the insulating layer but instead fall onto the machining protective layer 95. This makes removal of the particulate by-products or smear easier in the subsequent processes.

The cleaning operation is an operation of removing the particulate by-products 953 or smear 955 generated in the blind via 471 and removing the machining protective layer 95.

Specifically, the cleaning operation may comprise: a desmear process of removing the particulate by-products 953 or smear 955 by applying plasma or a desmear solution; and a protective-layer removal process of removing the machining protective layer 95 from the substrate that has undergone the removal process. In (a) of FIG. 3, ions 959 applied in a plasma-etching process are depicted together with the particulate by-products and smear.

After the desmear process, a cleaning process using chemicals such as an acid cleaning solution may be further performed. The cleaning process may be performed after the desmear process and before the protective-layer removal process, or may be performed after the protective-layer removal process.

When plasma desmear or a desmear solution is applied in the desmear, it has been necessary in the prior art to proceed in a manner that enables removal of particulate by-products and smear while minimizing damage to the insulating layer. Thus, if the desmear is too weak, removal of the by-products may be insufficient, and if the desmear is too strong, the insulating layer itself may be damaged. As a result, an excessive increase in the surface roughness of the insulating layer after desmear can be suppressed. If the surface roughness of the insulating layer becomes excessively large, it may result in partial exfoliation of the surface.

In the embodiments, these potential problems are addressed by applying the machining protective layer 95. Because the machining protective layer 95 protects the surface of the insulating layer, even when a strong desmear is applied, damage to the surface of the insulating layer can be suppressed.

The protective-layer removal process may be applied differently depending on the type of the machining protective layer 95.

By way of example, in the case of a metallic machining protective layer, the machining protective layer can be removed relatively easily by a method such as acid treatment. Alternatively, when etching is performed for the metal layer, the process can be carried out quickly and stably by utilizing materials already used in existing processes rather than introducing a new process.

By way of example, in the case of a machining protective layer containing a polymer resin, the machining protective layer can be removed relatively easily through a physical separation process.

Unlike ordinary cases in which polymer resins surrounding fillers contained in the insulating layer are removed during etching and the fillers become exposed on the surface, in the embodiments the degree of etching may be minimal due to the machining protective layer.

A difference between the surface roughness Ra of the insulating layer before formation of the machining protective layer 95 and the surface roughness Ra of the insulating layer after the cleaning operation may be 600 nm or less. The difference may be 500 nm or less, or 450 nm or less. The difference may be 20 nm or more.

The surface roughness Ra of the insulating layer after the cleaning operation may differ by 10-fold or less, or 9-fold or less, relative to the surface roughness Ra of the insulating layer before formation of the machining protective layer 95. The difference may be 1-fold or more.

There may be a difference between the diameter of a hole corresponding to the blind via in the machining protective layer 95 that is removed and the entrance diameter of the blind via at the surface of the formed insulating layer. For example, when a blind via is formed through the above processes, there may be a slight difference between the entrance diameter of the hole in the machining protective layer 95 corresponding to the blind via and the diameter of the entrance of the blind via at the surface of the insulating layer. The difference may be, for example, 4 µm or less, 3 µm or less, 2 µm or less, or 1 µm or less. The difference may be 0 µm or more. Accordingly, in consideration of this, the process may be performed such that the size of the hole formed on the machining protective layer 95 by laser irradiation is smaller than a predetermined entrance diameter of the blind via by the amount of the above difference.

According to another embodiment, a method for manufacturing a packaging substrate comprises: Operation A of preparing a glass core 10 having through vias and preparing a core electrically conductive layer 305 that is an electrically conductive layer disposed over the glass core; Operation B of preparing a core insulating layer 45 by disposing an insulating layer over a surface of the glass core 10; Operation C of forming blind vias 471 in the core insulating layer 45 according to the method of claim 1 for forming blind vias; Operation D of forming electrodes in the blind vias and forming an electrically conductive layer by providing an electrically conductive-layer pattern over the core insulating layer 45; and Operation E of preparing an upper insulating layer 47 by disposing an insulating layer over the electrically conductive layer.

The glass core 10 is a highly insulating material, which reduces the risk of parasitic elements and has the advantage of enabling large-area production compared with substrates such as silicon. Its non-conductive characteristics can provide the advantage of more stable operation particularly when high frequencies are applied.

The glass core 10 may be plate glass; for example, plate glass used in semiconductor processes may be applied. Specifically, for example, borosilicate plate glass or alkali-free plate glass may be used, but the embodiments are not limited thereto.

In the glass core 10, a through-type through via (through hole) that penetrates the plate glass in the thickness direction and/or a cavity that penetrates the plate glass in the thickness direction or forms a recessed surface may be provided. A through electrode may be formed in the core via so that electrical signals can be transmitted in the up–down direction of the glass core.

The glass core 10 may be 300 µm or more. The thickness of the glass core 10 may be 300 µm or more, 350 µm or more, 400 µm or more, 450 µm or more, or 500 µm or more. The thickness may be 2000 µm or less, 1800 µm or less, 1500 µm or less, 1200 µm or less, 1000 µm or less, 800 µm or less, or 700 µm or less. By applying a glass core having such a thickness, a glass core that serves as a support while ensuring durability above a certain level may be used.

In Operation B, the “surface” of the glass core 10 comprises the top surface, bottom surface, and the interior of the through via.

The glass core 10 has through electrodes, and a core electrically conductive layer 305 may be disposed in a predetermined pattern on the surface. Between them, a layer (not shown) for enhancing adhesion between the glass and the electrically conductive layer may be disposed—e.g., a primer layer or a sputtered layer may be provided—but the embodiments are not limited thereto ((a) of FIG. 1).

In Operation B, the core insulating layer 45 may be prepared by disposing and curing an insulating layer.

An insulating layer is disposed over the glass core 10. An insulating layer formed in the interior of the through electrode or on the surface of the glass core 10 is referred to as the core insulating layer 45 ((b) of FIG. 1), and an organic insulating layer, an inorganic insulating layer, or an organic–inorganic composite insulating layer may be applied. For example, an Ajinomoto build-up layer may be applied, but the embodiments are not limited thereto.

An upper electrically conductive layer 307 may be disposed over the core insulating layer 45. The pattern may be formed by a lithography process, and a process such as plating the electrically conductive layer 30 may be applied. Prior to copper plating, it is preferable to form a seed layer; coating a hybrid organic–inorganic primer layer containing a copper seed or forming a sputtered layer may be applied. Thereafter, copper plating is performed, and processes such as surface etching are further carried out to provide one layer of the upper electrically conductive layer ((c) of FIG. 1). In addition, by a process similar to that for the upper electrically conductive layer or the upper insulating layer, a lower electrically conductive layer 303 and a lower insulating layer 43 may be disposed under the core insulating layer 45.

The process of Operation C applies the above-described method of forming blind vias. Detailed description is omitted to avoid redundancy.

The method comprises Operation D of forming electrodes in the blind vias and forming an electrically conductive layer by providing an electrically conductive-layer pattern over the core insulating layer 45; and Operation E of disposing an insulating layer over the electrically conductive layer to prepare an upper insulating layer 47.

Specifically, a via electrode 37 may be formed in the blind via formed as shown in (b) of FIG. 3. Formation of the via electrode 37 may be carried out by disposing an electrically conductive layer in part or all of the blind via to enable vertical electrical connection, forming a pad 39 at the opening of the blind via, and forming an upper electrically conductive pattern over the insulating layer (upper insulating layer 47). During such processes, as needed, a seed layer may be formed, for example by sputtering, under the upper insulating layer in which the blind via is formed; however, this is omitted in the drawings and the above description. In the drawings, the upper insulating layer 47 is depicted as layers separated for ease of explanation; however, in the manufactured packaging substrate, the boundary between the core insulating layer and the upper insulating layer may not be substantially distinguished. Further, the upper insulating layer may be provided not as one layer but as two or more layers, and an electrically conductive pattern or electrode may be disposed in each layer. The upper insulating layer and the upper electrically conductive layer may each be formed in one or more, two or more, or three or more layers, and may be disposed in 20 or fewer, 16 or fewer, 12 or fewer, or 8 or fewer layers.

Similarly, the lower insulating layer may be provided not as one layer but as two or more layers, and an electrically conductive pattern or electrode may be disposed in each layer. The lower insulating layer and the lower electrically conductive layer may each be formed in one or more, two or more, or three or more layers, and may be disposed in 20 or fewer, 16 or fewer, 12 or fewer, or 8 or fewer layers.

Thereafter, an insulating cover layer (not shown) may be disposed over the uppermost one of the upper electrically conductive layers 307; for example, a PI (polyimide) layer having openings at locations where bumps will be formed may be provided as the insulating cover layer, but the embodiments are not limited thereto.

Thereafter, a solder resist layer (not shown) may be disposed over the uppermost one of the lower electrically conductive layers 303; for example, a solder resist layer having openings at locations to be connected to bumps and the like may be formed as the solder resist layer, but the embodiments are not limited thereto.

The method for forming blind vias and the method for manufacturing a packaging substrate according to the embodiments may make it easier to remove processing by-products in or around the via, and may minimize damage to the insulating layer around the via, thereby reducing defects of the packaging substrate and the like.

Although preferred embodiments of the present invention have been described in detail above, the scope of the present invention is not limited thereto, and various modifications and improvements made by those skilled in the art using the basic concepts of the present invention as defined in the following claims also fall within the scope of the present invention.

What is claimed is:

1. A method for forming blind vias in an insulator, comprising:
a protective-layer arranging operation of preparing a substrate in which a machining protective layer is disposed over an insulating layer;
a laser operation of forming a blind via at a predetermined position on the machining protective layer; and
a cleaning operation of removing particulate by-products or smear generated in the blind via and removing the machining protective layer.

2. The method of claim 1,
wherein the machining protective layer is a metal layer, and
the metal layer comprises titanium, a titanium–copper composite layer, or copper.

3. The method of claim 1,
wherein the machining protective layer is an organic layer or an organic–inorganic composite layer, and
the machining protective layer comprises a polyimide resin, a polyethylene terephthalate resin, a polyurethane resin, or a polyacrylic resin.

4. The method of claim 1,
wherein, when a laser is irradiated in the laser operation, a portion of the machining protective layer and a portion of the insulating layer are etched, and by-products scatter to form particulate by-products or smear.

5. The method of claim 1, wherein the cleaning operation comprises:
a desmear process of removing the particulate by-products or smear by applying plasma or a desmear solution; and
a protective-layer removal process of removing the machining protective layer from the substrate that has undergone the removal process.

6. The method of claim 1,
wherein the machining protective layer has a thickness of 10 µm or more and 500 µm or less.

7. The method of claim 1,
wherein a difference between a surface roughness Ra of the insulating layer before formation of the machining protective layer and a surface roughness Ra of the insulating layer after the cleaning operation is 600 nm or less.

8. The method of claim 1,
wherein a laser irradiation in the laser operation is ultraviolet having a pulse width of 400 nm or less, a pulse energy of 1 µJ or more, and a pulse repetition rate of 10 Hz or more.

9. A method for manufacturing a packaging substrate, comprising:
operation A of preparing a glass core having through vias and preparing a core electrically conductive layer disposed over the glass core;
operation B of preparing a core insulating layer by disposing an insulating layer on a surface of the glass core;
operation C of forming blind vias in the core insulating layer according to the method for forming blind vias in an insulator of claim 1;
operation D of forming electrodes in the blind vias and forming an electrically conductive layer by providing an electrically conductive-layer pattern on the core insulating layer; and
operation E of preparing an upper insulating layer by disposing an insulating layer on the electrically conductive layer.

10. The method of claim 9,
wherein, in operation B, the core insulating layer is prepared by disposing and curing the insulating layer.
